(19) United States
(12) Patent Application Publication
(10) Pub. No.: US 2019/0106811 A1
(43) Pub. Date: Apr. 11, 2019

(54) MANUFACTURING METHOD FOR SILICON CARBIDE CRYSTAL

(71) Applicant: GlobalWafers Co., Ltd., Hsinchu (TW)

(72) Inventors: Ching-Shan Lin, Hsinchu (TW); Jian-Hsin Lu, Hsinchu (TW); Chien-Cheng Liou, Hsinchu (TW); I-Ching Li, Hsinchu (TW)

(73) Assignee: GlobalWafers Co., Ltd., Hsinchu (TW)

(21) Appl. No.: 15/864,000

(22) Filed: Jan. 8, 2018

(30) Foreign Application Priority Data
Oct. 6, 2017 (TW) 106134503

(51) Int. Cl. C30B 29/36; C30B 17/00; C01B 32/956

(52) U.S. Cl. CPC C30B 29/36; C01P 2006/10; C01B 32/956; C30B 17/00

(57) ABSTRACT

A silicon carbide crystal and a manufacturing method for same are provided. A silicon carbide crystal seed used for the silicon carbide crystal has a crystal-growing surface with a surface roughness (Ra) less than 2.0 nm, and a thickness of the silicon carbide crystal seed is less than 700 μm. Therefore, the silicon carbide crystal grown from the silicon carbide crystal seed by sublimation method (which is also a PVT method) may have low basal plane dislocation (BPD) and low micropipe density (MPD).

### CROSS-REFERENCE TO RELATED APPLICATION

This application claims the priority benefit of Taiwan application serial no. 106134503, filed on Oct. 6, 2017. The entirety of the above-mentioned patent application is hereby incorporated by reference herein and made a part of specification.

### BACKGROUND

### Field of the Invention

The invention relates to a technique of a silicon carbide crystal and more particularly, to a silicon carbide crystal and a manufacturing method therefor.

### Description of Related Art

Silicon carbide (SiC) with a single crystal structure has characteristics, such as high temperature resistance and high stability, and thus, is widely applied in substrate materials of high-power device and high-frequency device. Among current methods for growing a silicon carbide crystal, a sublimation method, which is also referred to as a physical vapor transport (PVT) method, is much spotlighted.

In the sublimation method, SiC raw material powder is inductively heated by a temperature of 2200° C. or higher and sublimated to slowly grow single crystal by using a temperature gradient at a silicon carbide crystal seed position with a lower temperature. During a process of developing the crystal, in addition to a large-size chip being continuously developed for satisfying demands for manufacturing subsequent devices, technical focus points also include material characteristics, such as crystal quality (for example, a crystal has an issue with many defects in an initial growth period), and as a result, low quality wafers are increased.

For example, if the silicon carbide crystal has many defects, the defects also appear to SiC wafers manufactured by slicing the silicon carbide crystal, and all the defects even affect to an epitaxial layer during an epitaxy process, which causes affection in different degrees to capabilities of subsequently manufactured power devices. Taking basal plane dislocation (BPD) for example, the BPD in the silicon carbide crystal may extend to the epitaxial layer, which leads to Shockley-type stacking fault to various levels of the epitaxial layer, such that a leakage current of the device is increased, and performance and yield (i.e. the number of usable devices) are reduced.

### SUMMARY

According to an embodiment, the invention provides a silicon carbide crystal seed capable of saving growing cost and reducing structural defects of a silicon carbide crystal grown from the silicon carbide crystal seed.

According to another embodiment, the invention provides a silicon carbide crystal capable of reducing basal plane dislocation (BPD) and micropipe density (MPD).

According to yet another embodiment, the invention provides a manufacturing method for a silicon carbide crystal, by which a silicon carbide crystal with less defects can be grown from a silicon carbide crystal seed with a small thickness.

A silicon carbide crystal seed of the invention is employed to grow a silicon carbide crystal, and the silicon carbide crystal seed is featured in that a crystal-growing surface thereof has a surface roughness (Ra) less than 2.0 nm, and a thickness of the silicon carbide crystal seed is less than 700 μm.

In an embodiment of the invention, the crystal-growing surface of the silicon carbide crystal seed has a surface roughness (Ra) less than 0.5 nm.

In an embodiment of the invention, the crystal-growing surface of the silicon carbide crystal seed has a surface roughness (Ra) less than 0.3 nm.

In an embodiment of the invention, the silicon carbide crystal seed has a total thickness variation (TTV) less than 2 μm.

In an embodiment of the invention, the silicon carbide crystal seed has a warpage less than 30 μm.

In an embodiment of the invention, the silicon carbide crystal seed has a bow less than 20 μm.

A silicon carbide crystal of the invention is grown and obtained from the aforementioned silicon carbide crystal seed by a sublimation method (which is also referred to as a PVT method) and is featured in that the silicon carbide crystal has basal plane dislocation (BPD) of 2200/cm² or less.

In another embodiment of the invention, the silicon carbide crystal has a micropipe density (MPD) of 22/cm² or less.

In another embodiment of the invention, a nitrogen doping concentration of the silicon carbide crystal seed is 1×10¹⁵/cm³ to 1×10¹⁹/cm³.

In another embodiment of the invention, a buffer layer is further between the silicon carbide crystal and the silicon carbide crystal seed.

In another embodiment of the invention, a nitrogen doping concentration of the buffer layer is 10 times or less the nitrogen doping concentration of the silicon carbide crystal seed.

In another embodiment of the invention, the buffer layer is a multi-layer structure having at least three layers or more, a thickness of each layer is less than 0.1 μm, and a total thickness of the buffer layer is less than 0.1 mm.

A manufacturing method for a silicon carbide crystal of the invention includes the following steps. A silicon carbide crystal seed is provided, wherein the silicon carbide crystal seed has a Si-surface and a C-surface, the Si-surface is bonded to a seed shaft, the C-surface has a surface roughness (Ra) less than 2.0 nm, and a thickness of the silicon carbide crystal seed is less than 700 μm. Then, a sublimation method is performed on the silicon carbide crystal seed, so as to grow a buffer layer on the C-surface of the silicon carbide crystal seed, wherein a pressure for growing the buffer layer is more than 300 Torr, and a temperature therefor is between 1900° C. and 2100° C. The sublimation method is continuously performed, so as to grow a silicon carbide crystal on a surface of the buffer layer.

In yet another embodiment of the invention, a pressure for growing the silicon carbide crystal is less than 100 Torr, and a temperature therefor is between 2100° C. and 2200° C.

In yet another embodiment of the invention, an initial nitrogen doping concentration for growing the buffer layer is higher than a nitrogen doping concentration of the silicon carbide crystal seed, and the buffer layer is a single-layer structure with a gradient concentration.

Based on the above, the invention can achieve saving the growing cost and reducing the structural defect, such as the BPD and the MPD, of the silicon carbide crystal grown from the crystal seed simultaneously by reducing the surface roughness of the growing surface of the crystal seed and reducing the thickness of the crystal seed. In addition, according to the invention, the sufficiently thin silicon carbide crystal seed can be sliced, and with proper growing process parameters, the silicon carbide crystal seed in such thinness is not vaporized or deformed due to the high temperature during the period of the crystal growth by the sublimation method (which is also referred to as a PVT method).

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a silicon carbide crystal seed disposed in a physical vapor transport (PVT) apparatus according to an embodiment of the invention.

FIG. 2 is a flowchart of the preparation of a silicon carbide crystal according to another embodiment of the invention.

FIG. 3 shows a graph with respect to micropipe density (MPD) of Experiment example.

FIG. 4 shows a graph with respect to white defect density of Experiment example 4.

FIG. 5 shows a graph with respect to white defect density of a comparative example.

### DESCRIPTION OF EMBODIMENTS

The following description is supplemented by accompanying drawings to be illustrated more fully. However, the invention may be implemented in multiple different manners and is not limited to the embodiments described herein. In the drawings, each area, each portion and a size and a thickness of each layer may not illustrated according to actual proportions.

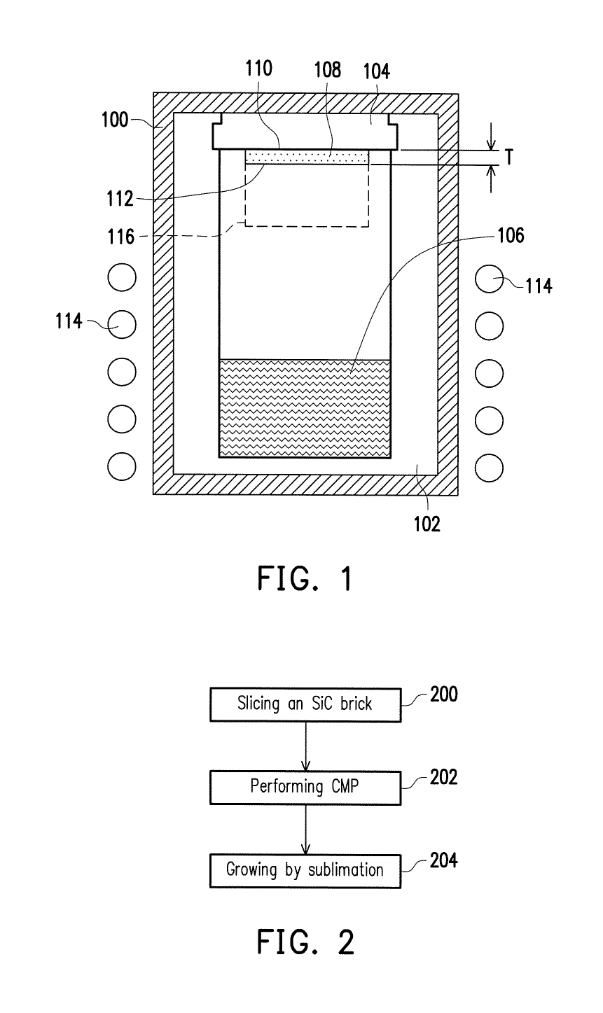

FIG. 1 is a schematic view of a silicon carbide crystal seed disposed in a physical vapor transport (PVT) apparatus according to an embodiment of the invention.

Referring to FIG. 1, the present embodiment uses a PVT method as an example for description, but the present embodiment is not limited to the PVT apparatus illustrated in FIG. 1 and is applicable to all kinds of apparatuses and manufacturing processes using the PVT method as a growing mechanism. A PVT apparatus generally has a furnace 100, and a graphite crucible 102 and a seed shaft 104 which are disposed in the furnace 100. A silicon carbide raw material 106 is placed over a bottom of the graphite crucible 102, the silicon carbide crystal seed 108 of the present embodiment is disposed on the seed shaft 104, a surface of the silicon carbide crystal seed 108 which is bonded to the seed shaft 104 is a bonding surface 110, and a face of the silicon carbide crystal seed 108 from which the silicon carbide crystal seed 108 is grown toward the silicon carbide raw material 106 is a growing surface 112. An induction coil 114 is further disposed outside the graphite crucible 102 for heating the silicon carbide raw material 106 in the graphite crucible 102.

In FIG. 1, the crystal-growing surface 112 of the silicon carbide crystal seed 108 has a surface roughness (Ra) less than 2.0 nm, which is preferable less than 0.5 nm and more preferably less than 0.3 nm. A thickness T of the silicon carbide crystal seed 108 may be less than 700 μm, thereby dramatically reducing cost of crystal growth. In an embodiment, the silicon carbide crystal seed 108 has a total thickness variation (TTV) less than 2 μm, a warpage less than 30 μm and a bow less than 20 μm.

Continuously referring to FIG. 1, when the silicon carbide raw material 106 over the bottom of the graphite crucible 102 is heated by the induction coil 114 to a high temperature, the silicon carbide raw material 106 is decomposed and directly sublimated without being through a liquid phase, which is driven by a temperature gradient to be transmitted to the growing surface 112 of the silicon carbide crystal seed 108, which is at a low temperature, or nucleating and growing, such that a silicon carbide crystal 116 is eventually grown and obtained. In the present embodiment, the silicon carbide crystal 116 grown from the growing surface 112 of the silicon carbide crystal seed 108 may have basal plane dislocation (BPD) of 2200/cm² or less, and as the surface roughness (Ra) of the growing surface 112 is reduced, the BPD may be reduced down to 10³/cm² or less. In addition, the silicon carbide crystal 116 may have a micropipe density (MPD) of 22/cm² or less, and the MPD may be further reduced down to 0/cm² as the surface roughness (Ra) of the growing surface 112 is reduced.

In addition, if the silicon carbide crystal 116 is employed for manufacturing an N-type substrate, a nitrogen doping concentration of the silicon carbide crystal seed 108 is, for example, between 1×10¹⁵/cm³ and 1×10¹⁹/cm³. Further, a buffer layer (not shown) may be formed between the silicon carbide crystal 116 and the silicon carbide crystal seed 108, and a nitrogen doping concentration of the buffer layer is, for example, 10 times or less the nitrogen doping concentration of the silicon carbide crystal seed 108. In an embodiment, the buffer layer may be a multi-layer structure having at least three layers or more, where a thickness of each layer is, for example, less than 0.1 μm, and a total thickness of the buffer layer s, for example, less than 0.1 mm.

FIG. 2 is a flowchart of the preparation of a silicon carbide crystal according to another embodiment of the invention.

Referring to FIG. 2, in step 200, a silicon carbide brick is sliced. In the present embodiment, the silicon carbide brick is first fixed on a work table and then sliced by using a plurality of slicing lines to form a plurality of silicon carbide wafers. Further, the slicing step is performed by maintaining the slicing lines at a linear velocity of at least 1510 m/minute, and the work table is moved at an adjustable feed speed. The adjustable feed speed refers to a speed gradually reduced from an initial speed to a lowest speed, which is then gradually increased to a final speed, where the initial speed is greater than the final speed, and the lowest speed is 6 mm/hr or more. In an embodiment, the initial speed is, for example, 12 mm/hr, the lowest speed is, for example, 6 mm/hr, and the final speed is, for example, 10 mm/hr. The slicing lines are preferably operated by being maintained at a linear velocity ranging from 1800 m/minute to 2800 m/minute.

Then, in step 202, a chemical mechanical polishing (CMP) process is performed, such that a silicon carbide crystal seed is formed by the silicon carbide wafers, where the silicon carbide crystal seed has a Si-surface and a C-surface. In the present embodiment, the crystal growth is performed by using the “C-surface” because a 4H type crystal is obtained by performing the crystal growth using the C-surface, while a 6H type crystal is obtained by performing the crystal growth using the Si-surface. A bandgap of the 4H type silicon carbide (4H-SiC) is greater than a bandgap of the 6H type silicon carbide (6H-SiC), and thus, the 4H-SiC obtained by the crystal growth using the C-surface may be adaptively applied to a high-power element. A process parameter with respect to step 202 may use a technique related to performing the CMP process on the silicon carbide.

A polished surface (i.e., the C-surface) of the silicon carbide crystal seed processed with the CMP process has a surface roughness (Ra) less than 2.0 nm, a thickness of the silicon carbide crystal seed is less than 700 μm, the silicon carbide crystal seed may refer to the description related to embodiment illustrated in FIG. 1 and thus, will not be repeated.

Then, in step 204, a sublimation method is performed on the silicon carbide crystal seed to grow a buffer layer on the silicon carbide crystal seed. The step of performing the sublimation method includes bonding the Si-surface to the seed shaft, growing the buffer layer on the C-surface of the silicon carbide crystal seed, and then growing the silicon carbide crystal on a surface of the buffer layer. In the present embodiment, a pressure for growing the buffer layer is, for example, more than 300 Torr, and a temperature therefor is controlled between 1900° C. and 2100° C. In another embodiment, the pressure for growing the silicon carbide crystal is, for example, less than 100 Torr, and the temperature therefor is controlled between 2100° C. and 2200° C. As the temperatures and the pressures for growing the buffer layer and the silicon carbide crystal are controlled within the aforementioned ranges, it may be ensured that the silicon carbide crystal seed with the thickness less than 700 μm is not vaporized and deformed due to the high temperature during the crystal growth process.

In addition, if the silicon carbide crystal of the present embodiment is employed for manufacturing an N-type substrate, nitrogen may be doped during the process of growing the buffer layer. In an embodiment, if an initial nitrogen doping concentration for growing the buffer layer is higher than the nitrogen doping concentration of the silicon carbide crystal seed, the buffer layer may be a single-layer structure with a gradient concentration or a multi-layer structure with each layer having a gradient concentration. In another embodiment, in the initial nitrogen doping concentration for growing the buffer layer is equal to the nitrogen doping concentration of the silicon carbide crystal seed, the buffer layer may be a multi-layer structure with a non-gradient concentration. In yet another embodiment, the initial nitrogen doping concentration for growing the buffer layer may also be less than the nitrogen doping concentration of the silicon carbide crystal seed.

Several experiments are provided below for verifying effects of the invention, but the contents of the experiments are not intent to limit the scope of the invention.

### Preparation Example 1

A silicon carbide brick having a nitrogen doping concentration about 1×10¹⁵/cm³ to 1×10¹⁹/cm³ is prepared and then, fixed on a work table. Thereafter, the silicon carbide brick is sliced by using slicing lines to form a plurality of silicon carbide wafers, and the work table is moved at an adjustable feed speed. The adjustable feed speed refers to a speed gradually reduced from an initial speed of 12 mm/hr to a lowest speed of 6 mm/hr, which is then gradually increased to a final speed of 10 mm/hr.

Then, a CMP process is performed on the silicon carbide wafers to form a silicon carbide crystal seed, where a pressure in a CMP period is greater than 15 g/cm², and a polishing speed is not less than 15 rpm and a time is 0.5 hr. A polished surface of the silicon carbide crystal seed after the CMP process has a surface roughness (Ra) slightly less than 5.0 nm, and a thickness of the silicon carbide crystal seed is less than 700 μm.

### Preparation Example 2

A silicon carbide crystal seed is manufactured in the same manner as Preparation example 1, but a time of the CMP process is changed to 0.75 hr. Thus, a polished surface of the silicon carbide crystal seed processed with the CMP process has a surface roughness (Ra) slightly less than 2.0 nm, and a thickness of the silicon carbide crystal seed is less than 700 μm.

### Preparation Example 3

A silicon carbide crystal seed is manufactured in the same manner as Preparation example 1, but a time of the CMP process is changed to 1.0 hr. Thus, a polished surface of the silicon carbide crystal seed processed with the CMP process has a surface roughness (Ra) slightly less than 1.0 nm, and a thickness of the silicon carbide crystal seed is less than 700 μm.

### Preparation Example 4

A silicon carbide crystal seed is manufactured in the same manner as Preparation example 1, but a time of the CMP process is changed to 1.75 hr. Thus, a polished surface of the silicon carbide crystal seed processed with the CMP process has a surface roughness (Ra) slightly less than 0.5 nm, and a thickness of the silicon carbide crystal seed is less than 700 μm.

### Preparation Example 5

A silicon carbide crystal seed is manufactured in the same manner as Preparation example 1, but a time of the CMP process is changed to 2.0 hr. Thus, a polished surface of the silicon carbide crystal seed processed with the CMP process has a surface roughness (Ra) slightly less than 0.3 nm, and a thickness of the silicon carbide crystal seed is less than 700 μm.

<Surface Analysis>

The silicon carbide crystal seed obtained in each of Preparation examples 1 to 5 by means of X-ray Diffraction (XRD) analysis to obtain a full width at half maximum (FWHM) of each preparation example. The results are recorded in Table 1 below.

### Experiment Example 1

In a condition that a pressure is greater than 300 Torr, and a temperature ranges from 1900° C. to 2100° C., a buffer layer is grown on a surface of the silicon carbide crystal seed of Preparation example 2, where the buffer layer is a single-layer structure with a gradient concentration, and a nitrogen doping concentration of the buffer layer is not over 10 times a nitrogen concentration in the crystal seed.

Then, in a condition that a pressure is less than 300 Torr, and a temperature ranges from 2100° C. to 2200° C., a silicon carbide crystal is grown on the aforementioned buffer layer.

In Experiment example 1, an initial nitrogen doping concentration for growing the buffer layer is greater than a nitrogen doping concentration of the silicon carbide crystal seed, a thickness of each layer of the buffer layer is <0.1 μm, and a total thickness of the buffer layer including at least three layers is <0.1 mm.

### Experiment Examples 2 to 4

The same method of Experiment example 1 is used, and a silicon carbide crystal is grown respectively on the surfaces of the silicon carbide crystal seeds of Preparation examples 3 to 5.

### Comparative Example

The same method of Experiment example 1 is used, and a silicon carbide crystal is grown on the surface (with Ra=5.0 nm) of the silicon carbide crystal seed of Preparation example 1.

<Crystal Defect Analysis>

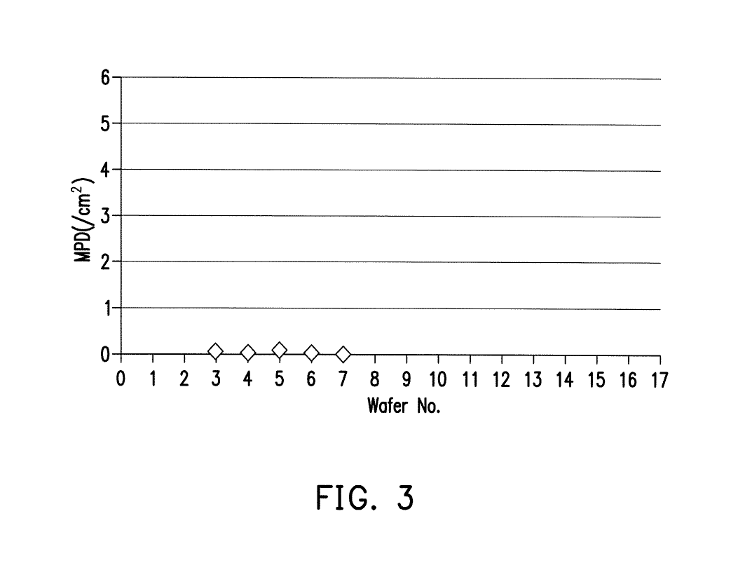

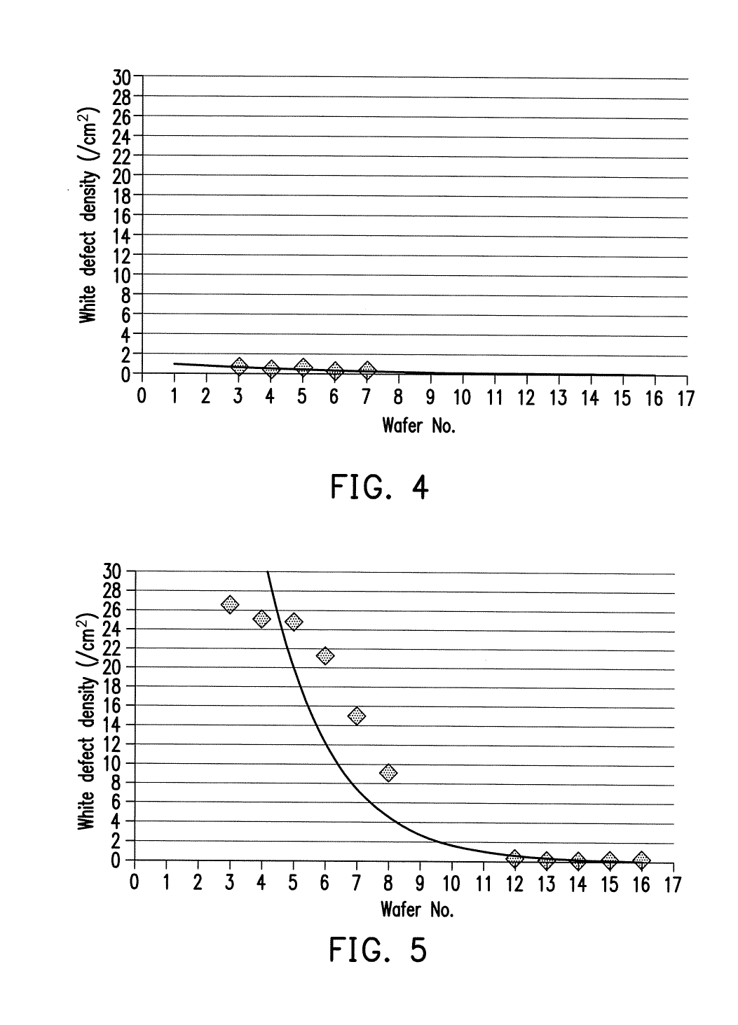

1. Analysis with respect to basal plane dislocation (BPD): the silicon carbide crystal is sliced into a plurality of wafers which are etched by Potassium hydroxide (KOH) at a temperature of 500° C. and then classified with a microscope, thereby calculating a BPD number density per unit area. The results are shown in Table 1 below.
2. Analysis with respect to micropipe density (MPD): the silicon carbide crystal is sliced into a plurality of wafers which are observed with an optical microscope (OM). The results are shown in Table 1 below. An MPD curve of Experiment example 4 is illustrated in FIG. 3.
3. Analysis with respect to inclusion defect density: the silicon carbide crystal of Experiment example 4 and the comparative example are respectively sliced into a plurality of wafers which are observed with the OM. The results are respectively illustrated in FIG. 4 and FIG. 5.

TABLE 1

| | Surface quality of crystal seed | | | |
|---|---|---|---|---|
| | Surface | | | |
| | roughness | XRD, FWHM | Defect type of crystal | |
| | Ra (nm) | arc (sec) | MPD (/cm²) | BPD (/cm²) |
| Comparative | <5.0 | 43 | 50 | 5500 |
| example | | | | |
| Experiment | <2.0 | 32 | 22 | 2200 |
| example 1 | | | | |
| Experiment | <1.0 | 20 | 5 | 1100 |
| example 2 | | | | |
| Experiment | <0.5 | 15 | 0 | 530 |
| example 3 | | | | |
| Experiment | <0.3 | 12 | 0 | 300 |
| example 4 | | | | |

According to Table 1, regarding FWHM of XRD, values of Experiment examples 1 to 4 are all less than values of the comparative example, which indicates that all the crystal seeds of the crystal seeds of Experiment examples 1 to 4 have preferable surface quality to that of the comparative example. Regarding MPD and BPD, values of Experiment examples 1 to 4 are all less than values of the comparative example, which indicates that all the crystal seeds of Experiment examples 1 to 4 have less defects than the comparative example and tend to having much less crystal defects as the surface roughness of the crystal seed is reduced. Specially, in Experiment examples 3 to 4, the MPD of both examples are 0, and BPD of both are less than 10³/cm².

In light of the foregoing, as the surface roughness of the growing surface of the silicon carbide crystal seed of the invention is small, the silicon carbide crystal grown therefrom has the BPD less than 2200/cm², such that the quality of the layers formed by the subsequent epitaxy process can be ensured. In addition, the thickness of the silicon carbide crystal seed of the invention can be less than 700 μm, which can contribute to reducing the growing cost, and with proper growing process parameters, the silicon carbide crystal seed in such thinness can be prevented from being vaporized or deformed.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A silicon carbide crystal seed, for growing silicon carbide crystal, wherein the silicon carbide crystal seed is featured in that:
a crystal-growing surface of the silicon carbide crystal seed has a surface roughness (Ra) less than 2.0 nm; and
a thickness of the silicon carbide crystal seed is less than 700 μm.

2. The silicon carbide crystal seed as recited in claim 1, wherein the crystal-growing surface of the silicon carbide crystal seed has a surface roughness (Ra) less than 0.5 nm.

3. The silicon carbide crystal seed as recited in claim 1, wherein the crystal-growing surface of the silicon carbide crystal seed has a surface roughness (Ra) less than 0.3 nm.

4. The silicon carbide crystal seed as recited in claim 1, wherein the silicon carbide crystal seed has a total thickness variation (TTV) less than 2 μm.

5. The silicon carbide crystal seed as recited in claim 1, wherein the silicon carbide crystal seed has a warpage less than 30 μm.

6. The silicon carbide crystal seed as recited in claim 1, wherein the silicon carbide crystal seed has a bow less than 20 μm.

7. A silicon carbide crystal, which is grown from the silicon carbide crystal seed as recited in claim 1 by a sublimation method, which is featured in that the silicon carbide crystal has basal plane dislocation (BPD) of 2200/cm² or less.

8. The silicon carbide crystal as recited in claim 7, wherein the silicon carbide crystal has a micropipe density (MPD) of 22/cm² or less.

9. The silicon carbide crystal as recited in claim 7, wherein a nitrogen doping concentration of the silicon carbide crystal seed is 1×10¹⁵/cm³ to 1×10¹⁹/cm³.

10. The silicon carbide crystal as recited in claim 7, further comprising a buffer layer between the silicon carbide crystal and the silicon carbide crystal seed.

11. The silicon carbide crystal as recited in claim 10, wherein a nitrogen doping concentration of the buffer layer is 10 times or less the nitrogen doping concentration of the silicon carbide crystal seed.

12. The silicon carbide crystal as recited in claim 10, wherein the buffer layer is a multi-layer structure having at least three layers or more, a thickness of each layer is less than 0.1 μm, and a total thickness of the buffer layer is less than 0.1 mm.

13. A manufacturing method for silicon carbide crystal, comprising:
providing a silicon carbide crystal seed, wherein the silicon carbide crystal seed has a Si-surface and a C-surface, the Si-surface is bonded to a seed shaft, the C-surface has a surface roughness (Ra) less than 2.0 nm, and a thickness of the silicon carbide crystal seed is less than 700 μm;
performing a sublimation method on the silicon carbide crystal seed to grow a buffer layer on the C-surface of the silicon carbide crystal seed, wherein a pressure for growing the buffer layer is more than 300 Torr, and a temperature for growing the buffer layer is between 1900° C. and 2100° C.; and
continuously performing the sublimation method, so as to grow a silicon carbide crystal on a surface of the buffer layer.

14. The manufacturing method for the silicon carbide crystal as recited in claim 13, wherein a pressure for growing the silicon carbide crystal is less than 100 Torr, and a temperature for growing the silicon carbide crystal is between 2100° C. and 2200° C.

15. The manufacturing method for the silicon carbide crystal as recited in claim 13, wherein an initial nitrogen doping concentration for growing the buffer layer is higher than a nitrogen doping concentration of the silicon carbide crystal seed, and the buffer layer is a single-layer structure with a gradient concentration.
